(19) United States
(12) Patent Application Publication
(10) Pub. No.: US 2024/0421270 A1
(43) Pub. Date: Dec. 19, 2024

(54) BACKLIGHTING UNIT COMPRISING A SIDE-EMITTING SEMICONDUCTOR CHIP

(71) Applicant: ams-OSRAM International GmbH, Regensburg (DE)

(72) Inventor: Ulrich STREPPEL, Regensburg (DE)

(21) Appl. No.: 18/580,747

(22) PCT Filed: Jul. 6, 2022
(86) PCT No.: PCT/EP2022/068689

§ 371 Date: Jan. 19, 2024

(30) Foreign Application Priority Data
Jul. 23, 2021 (DE) 10 2021 119 175.0

(51) Int. Cl. H01L 33/54; H01L 25/075; H01L 33/10

(52) U.S. Cl. CPC H01L 33/54; H01L 25/0753; H01L 33/10

(57) ABSTRACT

A backlighting unit includes at least one semiconductor chip, a reflector, and an encapsulation body. The semiconductor chip is configured to generate electromagnetic radiation. The encapsulation body has at least one depression. The semiconductor chip is arranged outside the depression and overlaps with the depression in top view of the encapsulation body. The semiconductor chip is a side-emitting semiconductor chip. The reflector has at least one frame-like sub-region, the opening of which is filled by the material of the encapsulation body and encloses the semiconductor chip and the depression of the encapsulation body in lateral directions. The encapsulation body projects beyond the sub-region in the vertical direction. The encapsulation body at least partially or completely covers edge regions of the sub-region in top view.

A backlighting unit is disclosed. An arrangement comprising a backlighting unit and a carrier is also disclosed.

In conventional backlighting systems using surface-emitting LEDs, a vertical thickness of a backlighting unit should be greater than 3 mm or greater than 5 mm, typically in the range of 8 mm to 10 mm, to provide a sufficiently large mixing area to achieve sufficient homogeneity.

One object is to specify a backlighting unit and an arrangement comprising a backlighting unit and a carrier with high compactness and reduced layer thickness without compromising the homogeneity of the light distribution.

This object is solved by the backlighting unit according to the independent claim. Further configurations and further embodiments of the backlighting unit and of the arrangement comprising a backlighting unit and a carrier are the subject of the dependent claims.

According to at least one embodiment of a backlighting unit, it has at least one semiconductor chip or a plurality of semiconductor chips. In particular, the semiconductor chips are side-emitting semiconductor chips, for example side-emitting LEDs. A side-emitting semiconductor chip is characterized in particular by the fact that it has a top side, a bottom side and side surfaces, wherein the radiation generated during operation of the semiconductor chip exits the semiconductor chip predominantly or exclusively via the side surfaces. The proportion of radiation emitted via the side surfaces can be at least 60%, 70%, 80% or at least 90% of the total radiation emitted from the semiconductor chip.

During operation of the backlighting unit, the semiconductor chip is configured to generate electromagnetic radiation, for example in the ultraviolet, infra-red or visible spectral range, such as the blue spectral range.

According to at least one embodiment of the backlighting unit, it has an encapsulation body. The encapsulation body can be formed from a radiation-transmissive material, in particular a transparent material, for example from silicone, epoxy or acrylate. The material of the encapsulation body has a refractive index that is in particular greater than 1.35, 1.4, 1.7 or greater than 2. The refractive index can also be less than 2, 1.7 or less than 1.5. The semiconductor chip or the plurality of semiconductor chips can be partially or completely embedded in the encapsulation body. In lateral directions, the semiconductor chip or the plurality of semiconductor chips can be completely enclosed by the material of the encapsulation body. However, it is also possible for the semiconductor chip or the plurality of semiconductor chips to be arranged below, in particular outside, the encapsulation body.

A lateral direction is understood to be a direction that runs parallel to a main extension surface of the encapsulation body or of the backlighting unit. A vertical direction is understood to be a direction that is perpendicular to the main extension surface of the encapsulation body or of the backlighting unit. The vertical direction and the lateral direction are orthogonal to each other.

According to at least one embodiment of the backlighting unit, the encapsulation body has at least one depression or several depressions. Along the vertical direction, the depression extends into the encapsulation body, but not throughout the encapsulation body. The depression thus has a bottom surface which is formed by a surface of the encapsulation body. For example, the bottom surface of the depression is flat or planar.

According to at least one embodiment of the backlighting unit, the semiconductor chip is arranged outside the depression. In top view of the encapsulation body, the semiconductor chip can overlap with its associated depression. In particular, the semiconductor chip is arranged in relation to the depression in such a way that the semiconductor chip is located below the bottom surface of the depression. In top view of the encapsulation body, the bottom surface of the depression can partially or completely cover the underlying semiconductor chip.

If electromagnetic radiation is generated by the semiconductor chip during operation of the backlighting unit, the electromagnetic radiation can be coupled into the depression via the bottom surface and/or side surfaces of the depression or be totally reflected at the bottom surface and/or side surfaces of the depression. The depression can be filled with a gaseous or solid material whose refractive index differs from the refractive index of the encapsulation body. Due to the different spatial orientations of the bottom surface and the side surfaces of the depression and due to a refractive index jump at the bottom surface or at the side surfaces of the depression, the radiation generated by the semiconductor chip can be scattered uniformly in lateral directions, in particular due to the total reflections, and in a forward direction.

In at least one embodiment of a backlighting unit, it has a semiconductor chip and an encapsulation body. The semiconductor chip is configured to generate electromagnetic radiation. The encapsulation body has at least one depression. The semiconductor chip is arranged outside the depression and overlaps with the depression when viewed from above on the encapsulation body. The semiconductor chip is a side-emitting semiconductor chip, for example a side-emitting LED.

With a side-emitting semiconductor chip, the emission in a forward direction is reduced compared to a surface-emitting semiconductor chip or a volume emitter. The emission of the radiation is rather fanned out in lateral directions and has a club-like shape in the luminance distribution. The occurrence of so-called hotspots in the luminance directly above the light source, in this case directly above the semiconductor chip, is thus suppressed. This reduces luminance gradients in the area above the semiconductor chip. The degree of homogeneity of the luminance distribution can also be increased due to the scattering at the bottom and side surfaces of the depression. A sufficient degree of homogeneity in the luminance distribution can also be achieved for a backlighting unit with a low vertical layer thickness, which is in particular less than 3 mm, 2.5 mm or less than 2 mm.

The backlighting unit can have a plurality of unit cells. The unit cells can have the same structure. The unit cells may be arranged in a matrix-like manner. In other words, the backlighting unit may have a plurality of unit cells arranged side by side in columns and rows. Each of the unit cells may include a semiconductor chip and a sub-region of the encapsulation body having a depression. In this disclosure, for the sake of clarity, the backlighting unit is often described in connection with only one unit cell. However, the features described with one unit cell can be used for all other unit cells of the backlighting unit or for the backlighting unit as a whole.

According to at least one embodiment of the backlighting unit, the semiconductor chip is enclosed by the encapsulation body at least in lateral directions. It is possible that the semiconductor chip is completely embedded within the encapsulation body, in particular with the exception of possible contact structures for external electrical contacting purposes. For example, the semiconductor chip can be arranged in the encapsulation body in such a way that a bottom side of the semiconductor chip is flush with a bottom side of the encapsulation body. In this case, the contact structures of the semiconductor chip can be accessible on the bottom side of the encapsulation body. It is also possible for the semiconductor chip to be arranged on a chip carrier and electrically connected to it, as a result of which the chip carrier is at least in places accessible on the bottom side of the encapsulation body. The semiconductor chip can be arranged in such a way that its top side faces a bottom surface of the depression.

According to at least one embodiment of the backlighting unit, the depression is pyramid-shaped or truncated pyramid-shaped. As the distance from the semiconductor chip increases, the depression can have a larger cross-section. For example, the depression has a bottom surface that is flat. The bottom surface of the depression can be larger or smaller than a cross-section of the semiconductor chip. For example, the bottom surface and the cross-section of the semiconductor chip can have the same geometry. For example, the bottom surface of the depression may be rectangular or square. However, the bottom surface can have other geometric shapes, for example a circular, elliptical or oval shape. It is also possible for the bottom surface to be rectangular, square, elliptical or circular, while the cross-section of the depression takes a different geometric shape as the distance from the bottom surface increases due to the deformation of the side surfaces of the depression.

According to at least one embodiment of the backlighting unit, the depression has side walls that are flat or convexly or concavely curved. The depression has edges that are rounded, for example. If one edge of the depression is rounded, two adjacent surfaces merge continuously at this edge. The transition area between these two surfaces is rather curved, rounded and not tapered. Such a rounded edge of the depression can be an inner edge between two side surfaces of the depression or between the bottom surface and a side surface of the depression. It is also possible for the rounded edge to be an outer edge of the depression, the outer edge being between a side surface of the depression and a surface of an encapsulation surrounding the depression.

According to at least one embodiment of the backlighting unit, the depression is filled with a gaseous medium, for example air. Alternatively or additionally, it is possible for the depression to be filled with a partially transparent material, a diffuse material, a colored material and/or a wavelength-converting material. Combinations of these are also possible.

According to at least one embodiment of the backlighting unit, it has a cover layer stack. The cover layer stack is located on the encapsulation body, for example, and can completely cover the depression. The cover layer stack can be arranged directly on the encapsulation body or mechanically connected to the encapsulation body via a connecting layer. The bonding layer can be formed from a bonding material that has a refractive index that is different from a refractive index of the encapsulating material. For example, the bonding material has a lower refractive index than the encapsulating material of the encapsulation body. The backlighting unit can have an intermediate area, in particular an air gap, between the cover layer stack and the encapsulation body. The intermediate area can be directly adjacent to the bonding layer, to the cover layer stack or to the encapsulation body. The presence of the air gap is due in particular to a surface curvature of the encapsulation body.

According to at least one embodiment of the backlighting unit, a vertical expansion of the backlighting unit is delimited by a top side of the cover layer stack and a bottom side of the encapsulation body. In other words, the top side of the cover layer stack and the bottom side of the encapsulation body may form outer surfaces of the backlighting unit.

A total vertical height of the backlighting unit given by a vertical distance between the top side of the cover layer stack and the bottom side of the encapsulation body is, for example, at most 3 mm, 2 mm or 1.5 mm. Due to the use of side-emitting semiconductor chips and the presence of the depressions, a high degree of homogeneity can be achieved despite the low layer thickness of the backlighting unit. For example, the total vertical height of the backlighting unit is from 0.5 mm to 3 mm, from 0.5 mm to 2.5 mm, from 1 mm to 2 mm, from 0.5 mm to 2 mm, from 0.5 mm to 1.5 mm or from 0.5 mm to 1 mm.

According to at least one embodiment of the backlighting unit, the encapsulation body has a top side that is curved, for example curved in places. Due to the curvature of the top side, an intermediate gap may be located in places between the encapsulation body and the cover layer stack. The intermediate gap can be filled with a gaseous medium, such as air, or with a solid medium, such as a bonding material. Due to the curvature, the top side of the encapsulation body can have lens-like structures that promote the propagation of radiation in lateral directions.

In places, the top side of the encapsulation body can be of convexly or concavely curved design. For example, the encapsulation body has a plurality of sub-regions, wherein each of the sub-regions has a top side that is curved. It is possible that the sub-regions of the encapsulation body are each assigned one-to-one to a unit cell of the backlighting unit, and vice versa. For example, the sub-regions of the encapsulation body each have a top side in the form of a lens, in particular a convex lens.

According to at least one embodiment of the backlighting unit, the cover layer stack has at least one or more layers from a group of functional layers. The group of functional layers may include phosphor layers, diffuser layers and/or so-called brightness enhancement films (BEF, DBEF). The functional layers are also known as light recycling layers and are used in particular for light mixing. The brightness enhancement films can be holographic mirror layers, semi-transparent mirror layers and/or linear prism layers, among others.

According to at least one embodiment of the backlighting unit, it has a reflector, wherein the reflector has at least one frame-like sub-region, the opening of which is filled by the material of the encapsulation body. The frame-like sub-region of the reflector can enclose the semiconductor chip and the depression of the encapsulation body in lateral directions. The reflector may have a plurality of frame-like sub-regions, wherein the frame-like sub-regions are each assigned one-to-one to one of the unit cells of the backlighting unit, and in particular vice versa. The sub-regions of the reflector can be directly adjacent to one another. In this case, the reflector is formed to be contiguous, in particular in one piece.

According to at least one embodiment of the backlighting unit, the encapsulation body protrudes along the vertical direction beyond the sub-region of the reflector, or beyond the entire reflector. For example, in top view, the encapsulation body covers the edge regions of the sub-region of the reflector at least partially or completely. In top view, the encapsulation body can partially or completely cover the reflector.

According to at least one embodiment of the backlighting unit, it has a plurality of semiconductor chips. For example, the backlighting unit has a plurality of unit cells each with one of the semiconductor chips. The encapsulation body may have a plurality of sub-regions each with a depression. The sub-regions of the encapsulation body can each laterally enclose one of the semiconductor chips, wherein the one semiconductor chip is arranged outside the depression associated with it and can overlap with its associated depression in top view of the encapsulation body.

For example, the sub-regions of the encapsulation body are each assigned to one of the unit cells of the backlighting unit. Each of the unit cells can have a semiconductor chip, a sub-region of the encapsulation body with the depression and a sub-region of the reflector. It is possible that the cover layer stack is formed as a common cover layer stack for several unit cells, in particular for all unit cells. It is also possible that each of the unit cells has exactly one side-emitting semiconductor chip and a sub-region of the encapsulation body with exactly one depression.

According to at least one embodiment of the backlighting unit, it has a common reflector. The common reflector has a plurality of contiguous sub-regions, each of which is assigned to one of the unit cells. In particular, the encapsulation body with its sub-regions is formed to be contiguous. For example, the sub-regions of the encapsulation body each have a curved top side in the form of a lens.

According to one embodiment of an arrangement, the arrangement comprises a backlighting unit, in particular a backlighting unit described herein, and a carrier, wherein the backlighting unit is arranged on the carrier. The backlighting unit can be mechanically, thermally and/or electrically connected to the carrier. For example, the carrier is a circuit board (Printed Circuit Board). The semiconductor chip or the plurality of semiconductor chips can be electrically contacted externally via contact structures on the carrier. It is also possible that transistors for controlling the semiconductor chips are arranged on the carrier or integrated in the carrier.

According to one embodiment of the arrangement, the carrier has a structured top side facing the backlighting unit. The structured top side is configured for instance to scatter the electromagnetic radiation, which is generated by the semiconductor chip and impinges on the carrier, and thus to prevent possible hotspots. In other words, the structured top side is particularly configured to achieve back-reflection of the electromagnetic radiation generated by the semiconductor chip and impinging on the carrier to larger angles, since otherwise there is a risk that an area of the carrier around the semiconductor chip will light up brightly and thus possibly lead to a hotspot. For example, the top side of the carrier has elevations and/or depressions that are located in the immediate vicinity of the semiconductor chip when viewed from above. If electromagnetic radiation generated by the semiconductor chip is emitted in the direction of the carrier, it is not directly reflected back in a forward direction, but is scattered in lateral directions. This also increases the degree of homogeneity of the luminance distribution and prevents the formation of possible hotspots.

The following text describes other aspects of the present disclosure, each aspect being numbered to facilitate reference to features of other aspects.

Aspect 1: A backlighting unit comprising at least one semiconductor chip and an encapsulation body, wherein
the semiconductor chip is configured to generate electromagnetic radiation,
the encapsulation body has at least one depression,
the semiconductor chip is arranged outside the depression and overlaps with the depression in top view of the encapsulation body, and
the semiconductor chip is a side-emitting semiconductor chip.

Aspect 2: Backlighting unit according to aspect 1,wherein the semiconductor chip is enclosed by the encapsulation body at least in lateral directions.

Aspect 3: The backlighting unit according to any one of the preceding aspects, wherein the depression is pyramidal or truncated pyramidal and has a cross-section that increases in size with increasing distance from the semiconductor chip, the depression having a bottom surface that is flat.

Aspect 4: The backlighting unit according to any one of the preceding aspects, wherein the depression has side walls that are convexly or concavely curved.

Aspect 5: The backlighting unit according to any one of the preceding aspects, wherein the depression has edges that are rounded.

Aspect 6: The backlighting unit according to any one of the preceding aspects, wherein the depression is filled with a gaseous medium.

Aspect 7: The backlighting unit according to any one of Aspects 1 to 6, wherein the depression is filled with a partially transparent material, a diffuse material, a colored material and/or a wavelength-converting material.

Aspect 8: The backlighting unit according to any one of the preceding aspects, comprising a cover layer stack overlying the encapsulation body and completely covering the depression.

Aspect 9: The backlighting unit according to the preceding aspect, wherein a vertical expansion of the backlighting unit is delimited by a top side of the cover layer stack and a bottom side of the encapsulation body, and wherein a total vertical height of the backlighting unit given by a vertical distance between the top side of the cover layer stack and the bottom side of the encapsulation body is at most 3 mm.

Aspect 10: The backlighting unit according to any one of Aspects 8 to 9, wherein the encapsulation body has a top side that is curved, as a result of which there is in places an intermediate gap between the encapsulation body and the cover layer stack.

Aspect 11: The backlighting unit according to any one of aspects 8 to 10, wherein the cover layer stack comprises at least one or more layers of a group of functional layers, wherein the group of functional layers includes a phosphor layer, a diffuser layer and/or so-called brightness enhancement films.

Aspect 12: The backlighting unit according to one of the preceding aspects comprising a reflector, wherein the reflector has at least one frame-like sub-region, the opening of which is filled by the material of the encapsulation body and encloses the semiconductor chip and the depression of the encapsulation body in lateral directions.

Aspect 13: The backlighting unit according to the preceding aspect, wherein the encapsulation body extends beyond the sub-region along the vertical direction, wherein the encapsulation body covers edge regions of the sub-region at least partially or completely in top view.

Aspect 14: The backlighting unit according to any one of the preceding aspects comprising a plurality of semiconductor chips, wherein
the backlighting unit has a plurality of unit cells each comprising one of the semiconductor chips,
the encapsulation body has a plurality of sub-regions, each with a depression,
the sub-regions of the encapsulation body each laterally enclose one of the semiconductor chips, wherein the one semiconductor chip is arranged outside its associated depression and overlaps with it associated depression in top view of the encapsulation body, and
the sub-regions of the encapsulation body are each assigned to one of the unit cells.

Aspect 15: The backlighting unit according to the preceding aspect comprising a common reflector, wherein
the common reflector has a plurality of contiguous sub-regions, each of which is associated with one of the unit cells, and
the encapsulation body with its sub-regions is contiguous.

Aspect 16: An arrangement comprising the backlighting unit according to any one of the preceding aspects and a carrier, wherein
the backlighting unit is arranged on the carrier, and
the semiconductor chip is electrically externally connectable via contact structures on the carrier.

Aspect 17: An arrangement comprising the backlighting unit according to any one of aspects 1 to 15 and a carrier, wherein
the backlighting unit is arranged on the carrier,
the carrier has a structured top side facing the backlighting unit, and
the structured top side is configured to scatter the electromagnetic radiation, which is generated by the semiconductor chip and impinges on the carrier, and thus to prevent possible hotspots.

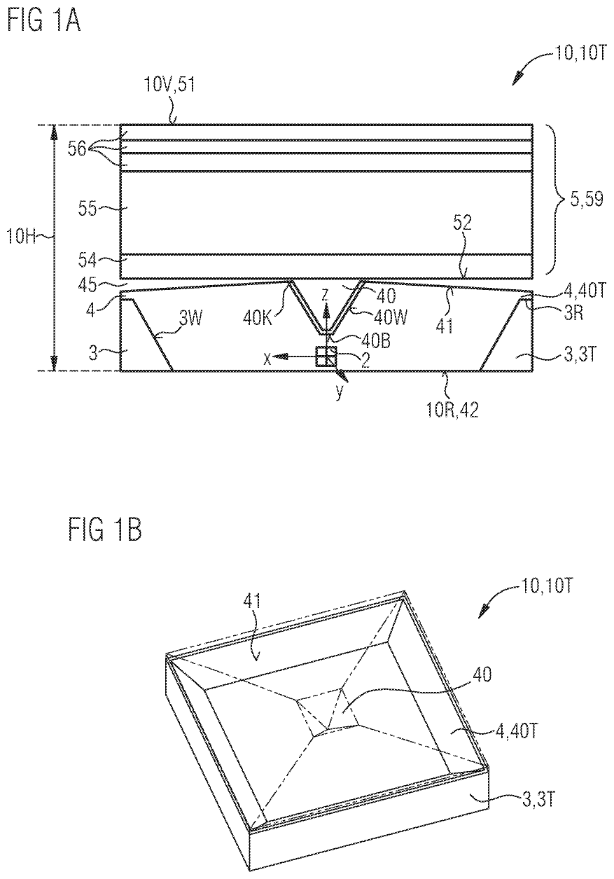

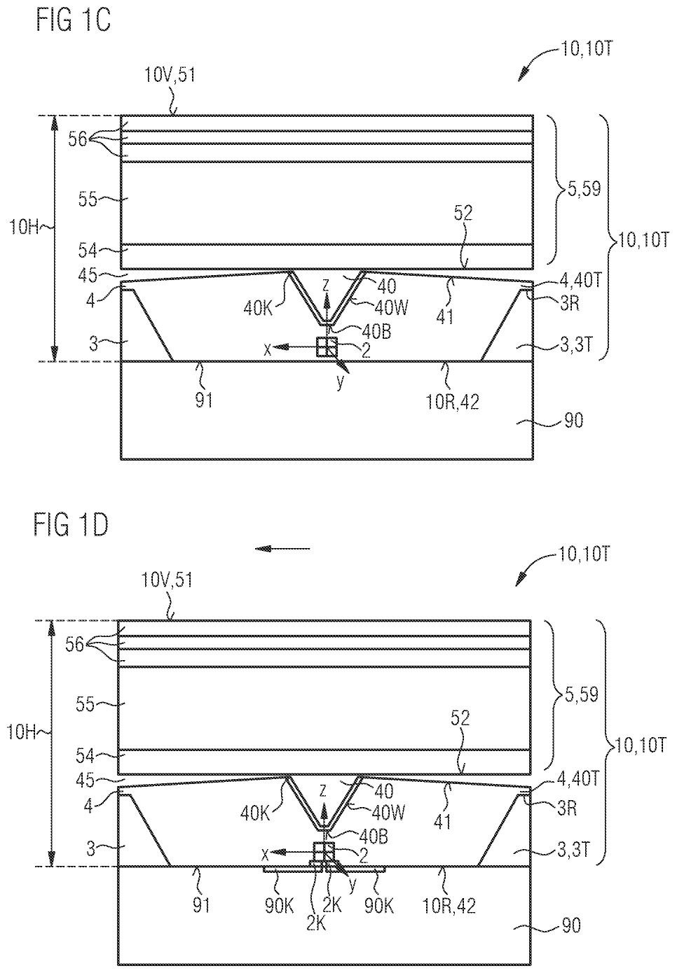

Further embodiments and further implementations of the backlighting unit or of the arrangement comprising the backlighting unit and the carrier will be apparent from the exemplary embodiments explained below in conjunction with FIGS. 1A to 6E.

FIGS. 1A and 1B show schematic representations of an exemplary embodiment of a backlighting unit using a unit cell in sectional view and in top view,

FIGS. 1C and 1D show schematic representations of some exemplary embodiments of an arrangement with a backlighting unit and a carrier, in each case in top view,

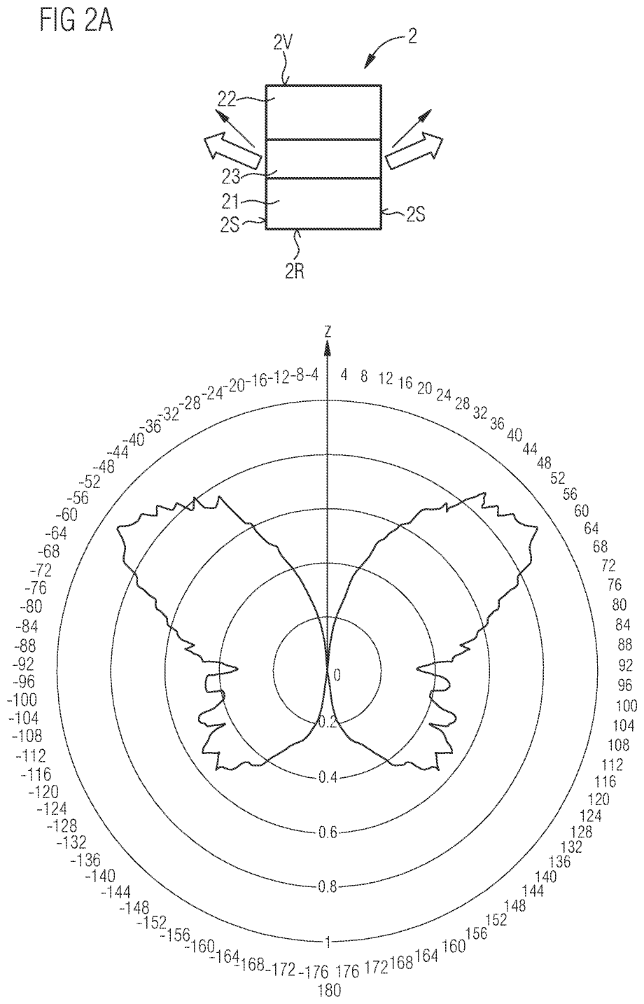

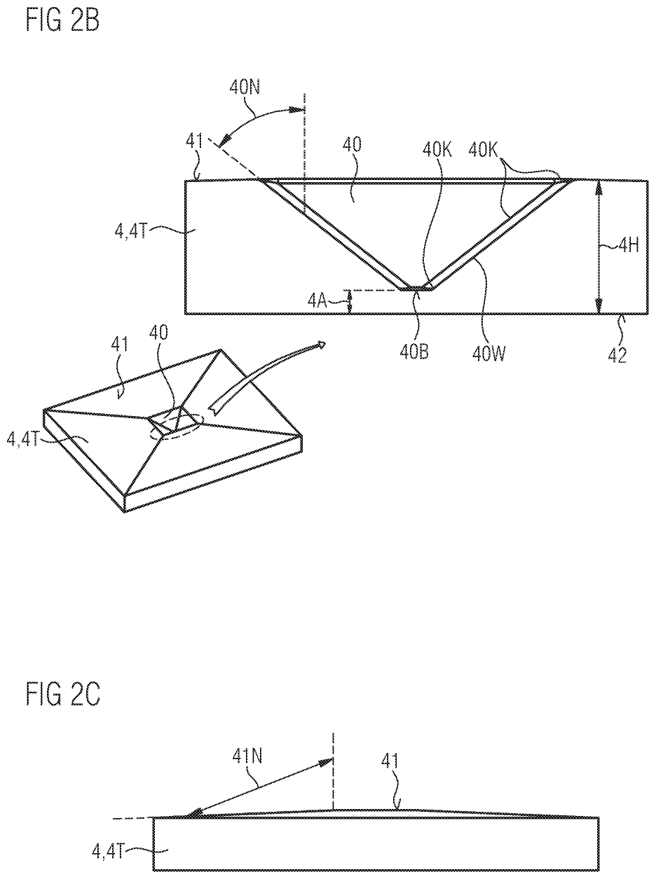

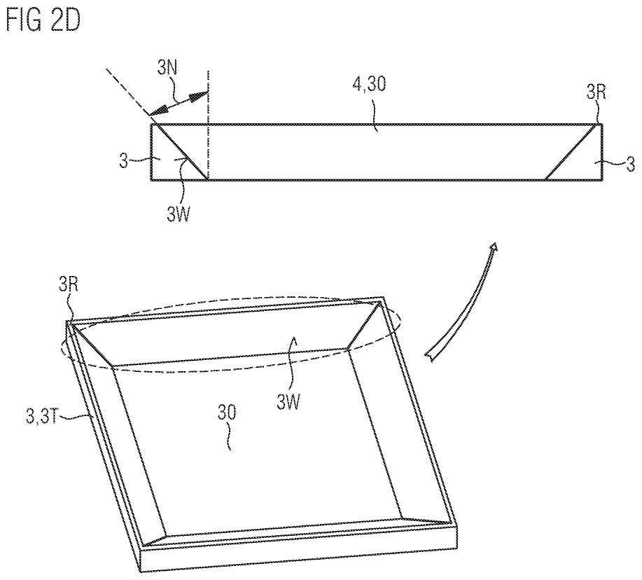

FIG. 2A shows schematic representation of a semiconductor chip of the backlighting unit and a luminance distribution of such a semiconductor chip,

FIGS. 2B and 2C show schematic representations of a sub-region of an encapsulation body of the backlighting unit in sectional views,

FIG. 2D shows schematic representation of a reflector of the backlighting unit,

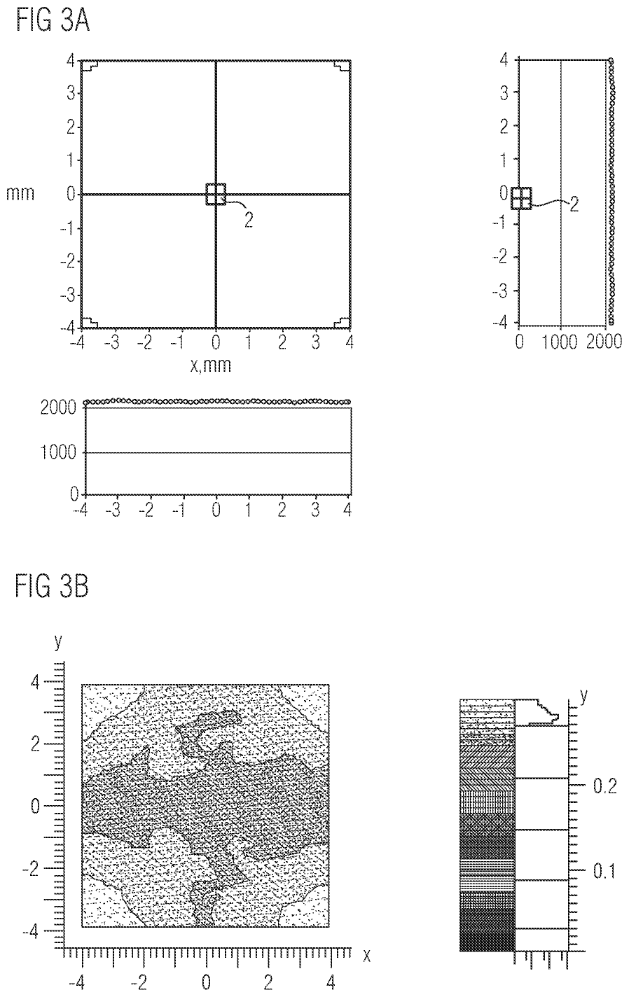

FIGS. 3A and 3B show schematic representations of the results of a simulation with regard to the luminance and chromaticity distribution of a unit cell,

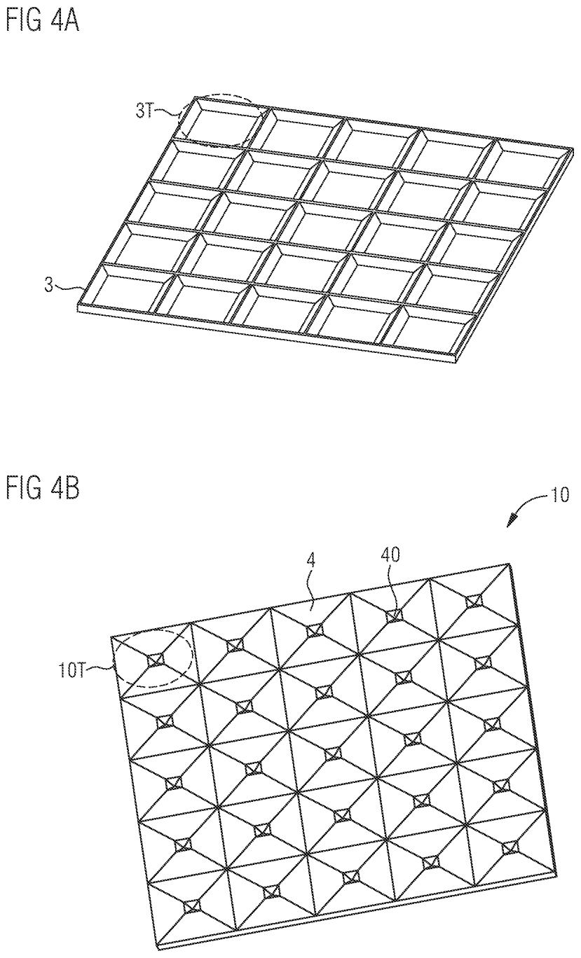

FIG. 4A shows schematic representation of a common reflector of a backlighting unit with a plurality of unit cells,

FIG. 4B shows schematic representation of a backlighting unit with a plurality of unit cells,

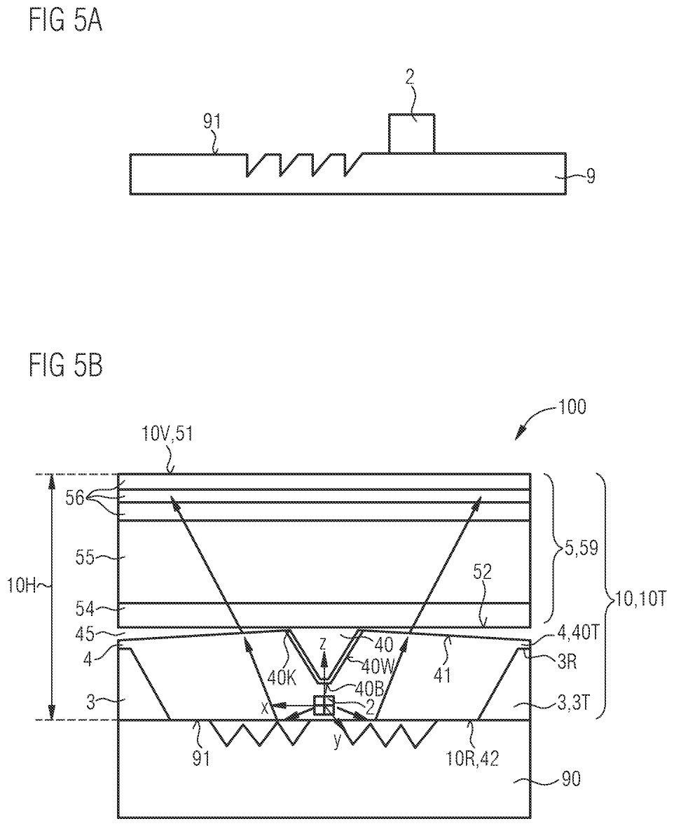

FIGS. 5A and 5B show schematic representations of a structured carrier and of an arrangement with a backlighting unit on a structured carrier, and

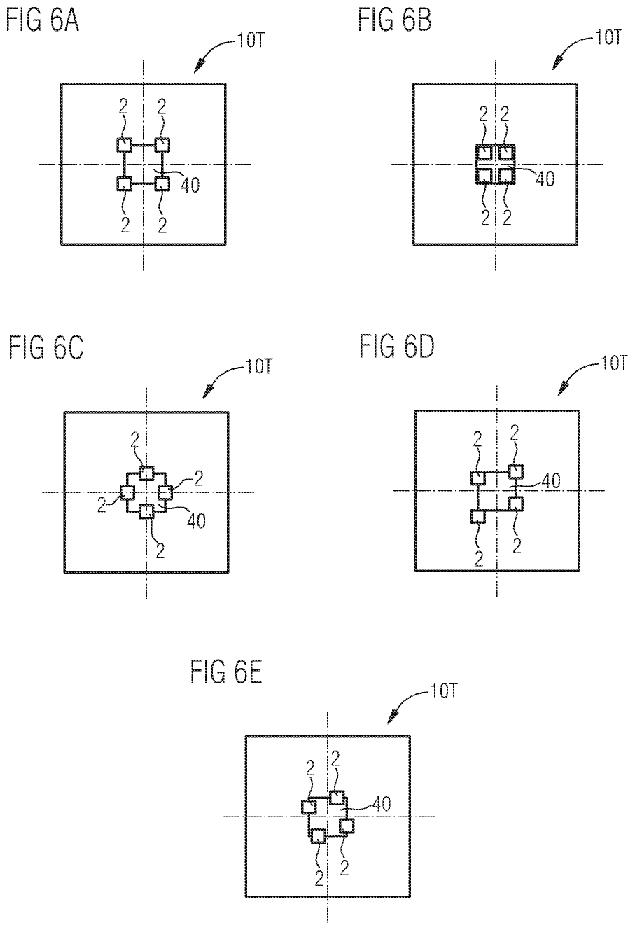

FIGS. 6A, 6B, 6C, 6D and 6E show schematic representations of various exemplary embodiments of a unit cell with several semiconductor chips.

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

FIG. 1A shows a backlighting unit 10, more precisely a unit cell 10T of the backlighting unit 10. The backlighting unit can have a plurality of such unit cells 10T. The unit cells 10T can be directly adjacent to one another. In particular, the backlighting unit 10 has a plurality of rows 10 and columns of the unit cells 10T. In other words, the unit cells 10T are arranged in a matrix-like manner. In the following, the backlighting unit 10 is often described in connection with one unit cell 10T for the sake of simplicity.

The backlighting unit 10 has at least one semiconductor chip 2, which is configured to generate electromagnetic radiation. The backlighting unit 10 has an encapsulation body 4 comprising at least one depression 40. The encapsulation body 4 has a plurality of sub-regions 40T, each of which in particular is assigned to exactly one of the unit cells 10T. For example, the sub-regions 40T are integral components of a contiguous encapsulation body 4. Each of the sub-regions 40T can have a depression 40, in particular exactly one depression 40.

Along the vertical direction, the depression 40 extends from a top side 41 of the encapsulation body 4 into the encapsulation body 4 and thus forms a blind hole in the encapsulation body 4. The top side 41 of the encapsulation body 4 or of the sub-region 40T of the encapsulation body 4 may be curved, in particular convexly curved. Apart from the position of the depression 4, the top side 41 can take the form of a lens. A bottom side 42 of the encapsulation body 4 or of the sub-region 40T of the encapsulation body 4 can be flat. The bottom side 42 may be freely accessible. In particular, a bottom side 10R of the backlighting unit 10 is formed in places by the bottom side 42 of the encapsulation body 4.

The depression 4 has a bottom surface 40B, which is flat, for example. The depression 4 has side surfaces or side walls 40W, which may be flat or convexly or concavely curved. The depression 4 has edges 40K, which are sharp-edged or rounded. The edges 40K may be inner edges, for example between adjacent side walls 40W or between the bottom surface 40B and the side walls 40W, or outer edges, for example between the top side 41 of the encapsulation body 4 and the side walls 40W.

The vertical direction z and lateral directions x and y are shown schematically in FIG. 1A. Along the vertical direction and with increasing distance from the bottom surface 40B, the depression 40 has an increasing lateral cross-section. In particular, the depression 40 is pyramid-shaped, such as truncated pyramid-shaped. The bottom surface 40B can be quadrangular, rectangular, square, circular or elliptical or can have another geometric shape.

The backlighting unit 10 has at least one semiconductor chip 2. In particular, the backlighting unit 10 has a plurality of semiconductor chips 2 arranged in different unit cells 10T. For example, the semiconductor chips 2 are side-emitting semiconductor chips 2. It is possible that each sub-region 40T of the encapsulation body 4 has exactly one depression and exactly one side-emitting semiconductor chip 2.

According to FIG. 1A, the semiconductor chip 2 is arranged outside the depression 40. In top view of the encapsulation body 4, the depression 40 overlaps with the semiconductor chip 2. The bottom surface 40B of the depression 4 can partially or completely cover the semiconductor chip 2. It is possible that the geometry of the bottom surface 40B of the depression 4 is adapted to the geometry of the semiconductor chip 2. For example, the bottom surface 40B and a cross-section of the semiconductor chip 2 have the same geometric shape.

According to FIG. 1A, the semiconductor chip 2 is enclosed in lateral directions by the encapsulation body 4. For example, a top side 2V and all side surfaces 2S of the semiconductor chip 2 (see FIG. 2A) may be covered, in particular completely covered, by the material of the encapsulation body 4. A bottom side 2R of the semiconductor chip 2 can also be partially or completely covered by the material of the encapsulation body 4. In deviation from FIG. 1A, it is possible for a bottom side 2R of the semiconductor chip 2, for example with electrical contact points on the bottom side 10R of the backlighting unit 10, to be freely accessible. The semiconductor chip 2 can thus be partially or completely embedded in the encapsulation body 4. In deviation from FIG. 1A, it is possible that the semiconductor chip 2 is located outside the encapsulation body 4.

The backlighting unit 10 has a reflector 3. The reflector 3 can be continuous. The bottom side 10R of the backlighting unit 10 may be formed in places by the surface of the reflector 3. For example, the reflector 3 has integral sub-regions 3T, each of which is assigned to one of the unit cells 10T. The reflector 3 has a plurality of openings, each of which is assigned to one of the unit cells 10T. Along the vertical direction, the opening extends in particular through the reflector 3 and is thus formed in particular as a through-hole. For example, each of the sub-regions 3T of the reflector 3 has such an opening. The opening/s is/are filled with the material of the encapsulation body 4. The reflector 3 or the sub-region 3T of the reflector 3 has, in particular, oblique side walls 3W. The side walls 3W can be completely covered by the material of the encapsulation body 4.

The reflector 3 has upper edge regions 3R, which can be completely covered by the material of the encapsulation body 4. The encapsulation body 4 protrudes along the vertical direction, in particular beyond the reflector 3. Due to the covering of the reflector 3, the sub-regions 40T, in particular all sub-regions 40T of the encapsulation body 4 can be connected to each other. In this sense, the encapsulation body 4 is formed in one piece.

The backlighting unit 10 has a cover layer stack 5, in particular a common cover layer stack 5, for all unit cells 10T. The cover layer stack 5 is arranged on the encapsulation body 4. Due to the curvature of the top side 41 of the encapsulation body 4, there may be an intermediate gap 45 between the encapsulation body 4 and the cover layer stack 5. The intermediate gap 45 can be filled at least in places with a gaseous medium, such as air. It is also possible for the intermediate gap 45 to be filled in places with a solid medium, such as a bonding material.

The cover layer stack 5 has a plurality of functional layers 59. The functional layer 59 may be a phosphor layer 54, such as in the form of a phosphor film, a diffuser layer 55, such as in the form of a volume diffuser film, or a brightness enhancement film (BEF, DBEF) 56. The phosphor layer 54 may have light-emitting substances that can convert electromagnetic radiation of short wavelength into electromagnetic radiation of longer wavelength. For example, the semiconductor chip 2 is configured to generate electromagnetic radiation in the blue or ultraviolet spectral range. This radiation can be converted by the phosphor layer 54 into electromagnetic radiation in the yellow, green or red spectral range. The diffuser layer 55 and the brightness enhancement layer 56 are configured in particular to mix the converted radiation. According to FIG. 1A, the cover layer stack 5 has, among other things, a DBEF layer 56 and two BEF layers 56.

The cover layer stack 5 has a top side 51 and a bottom side 52, with the bottom side 52 facing the encapsulation body 4. The bottom side 52 may be formed by a surface of the phosphor layer 54. In particular, the top side 51 is an exposed surface of the cover layer stack 5, which may be formed by a surface of the brightness enhancement film 56. A top side 10V of the backlighting unit 10 may be formed by the top side 51 of the cover layer stack 5.

The backlighting unit 10 has a total vertical height 10H. In particular, the total vertical height 10H indicates an average vertical expansion of the backlighting unit 10. The vertical expansion of the backlighting unit is delimited in particular by the top side 51 of the cover layer stack 5 and the bottom side 42 of the encapsulation body 4. In particular, the total vertical height 10H of the backlighting unit 10, which is given by a vertical distance between the top side 51 of the cover layer stack 5 and the bottom side 42 of the encapsulation body 4, is at most 3 mm, 2.5 mm, 2 mm or at most 1.5 mm.

FIG. 1B shows a schematic representation of a unit cell 10T without the cover layer stack 5. The depression 40 is arranged centrally in the sub-region 40T of the encapsulation body 4. In particular, the encapsulation body 4 completely covers the sub-region 3T of the reflector 3 in top view. Within the unit cell 10T, the sub-region 40 of the encapsulation body 4 has a reduced vertical thickness from the depression 40 towards the potting edge region. The depression 40 is located above the light source, for example above the semiconductor chip 2, and has a conical or pyramid-like shape.

FIG. 1C shows an arrangement 100 with a backlighting unit 10, which is shown schematically in particular in FIG. 1A, and a carrier 90. The carrier 90 can be a circuit board. In particular, the backlighting unit 10 is mechanically and electrically conductively connected to the carrier 90. The carrier 90 can have electrical contact structures 90K on its top side 91, via which the semiconductor chip 2 or the plurality of semiconductor chips 2 are externally electrically connectable. In particular, the top side 91 is highly reflective and may have a reflectance R greater than 90% or greater than 95%. For example, the top side 91 of the carrier 90 has a white Lambertian scattering characteristic.

As shown schematically in FIG. 1D, the semiconductor chip 2 may have contact structures 2K which are freely accessible on the bottom side 10R of the backlighting unit 10 and can be electrically conductively connected to the contact structures 90K of the carrier 90. Alternatively, it is possible for the semiconductor chip 2 to be arranged on a chip carrier that has the contact structures 2K.

FIG. 2A shows a side-emitting semiconductor chip 2 of the backlighting unit and a luminance distribution of such a semiconductor chip 2.

The semiconductor chip 2 can have a first semiconductor layer 21, a second semiconductor layer 22 and an active zone 23, wherein the active zone 23 is arranged in the vertical direction between the first semiconductor layer 21 and the second semiconductor layer 22 and is configured in particular for generating electromagnetic radiation. The first semiconductor layer 21 and the second semiconductor layer 22 can be formed to be n-conducting or p-conducting, or vice versa. The semiconductor chip 2 is formed as a side-emitting semiconductor chip 2, with a main part of the emitted radiation emerging from the semiconductor chip 2 at the side surfaces 2S. In particular, the emission is not or hardly at all via the top side 2V or via the bottom side 2R. An angle-dependent radiation emission of such a semiconductor chip 2 is shown schematically on the right-hand side of FIG. 2A. A main part of the radiation is not emitted directly in a vertical forward direction z. The emission is more club-like and is fanned out in lateral directions. The main direction of radiation forms an angle of between 35° and 65° with the forward direction z.

The semiconductor chip 2 is arranged in the unit cell 10T in particular in such a way that the top side 2V of the bottom surface 40B faces the depression 40. Such an arrangement of the semiconductor chip 2 relative to the depression 40 increases the degree of homogeneity in the luminance distribution of the unit cell 10T.

FIG. 2B shows a schematic representation of a sub-region 4T of an encapsulation body 4 with the depression 40. In particular, the encapsulation body 4 is formed from a material that is transmissive, in particular transparent, to the electromagnetic radiation generated by the semiconductor chip 2. For example, the encapsulation body 4 is made of silicone, epoxy, acrylate or a similar material. In particular, the material has a refractive index greater than 1.35.

The encapsulation body 4 has a vertical height 4H which is, for example, from 0.5 mm to 1.5 mm, for instance around 0.9 mm. The depression 40 has a vertical depth that is, for example, from 0.2 mm to 1 mm, for instance from 0.2 mm to 0.8 mm inclusive or from 0.2 mm to 0.5 mm inclusive. A vertical distance 4A between the bottom side 42 of the encapsulation body 4 and the bottom surface 40B of the depression 40 may be from 0.2 mm to 1 mm, for instance from 0.2 mm to 0.8 mm, or from 0.2 mm to 0.5 mm, for instance around 0.35 mm. For example, a ratio 4A to 4H is from 0.3 to 0.7, for instance from 0.3 to 0.5, or from 0.4 to 0.6.

Preferably, the edges 40K are rounded, as a result of which the radiation coupled into the depression 40 is scattered as far as possible in all lateral directions. As shown schematically in FIG. 2B, the bottom surface 40B is planar. The side walls 40W of the depression 40 form an acute angle of inclination 40N with a vertical solder in particular. For example, the angle of inclination 40N is from 30° to 60°, for instance from 35° to 55°, for instance around 52°. The side walls 40W may be planar or convexly or concavely curved.

The depression 40 can have a rectangular, circular or elliptical shape, or a rectangular shape with strongly rounded corners. The cross-section of the depression 40 can take on various shapes. For example, the bottom surface 40B and an upper opening of the depression 40 have different shapes. For example, a circular bottom surface 40B is transformed into a rectangle in the direction of the upper opening of the depression 40.

FIG. 2C shows a schematic representation of a sub-region 4T of the encapsulation body 4 in sectional view. The top side 41 of the sub-region 4T tapers towards the potting edge region. An angle of inclination 41N of the top side 41 of the encapsulation body 4 or of the sub-region 4T of the encapsulation body 4 to the vertical plummet can be between 90° and 120°, for example between 95° and 120°. The top side 41 of the sub-region 4T can take the form of the surface of a convex lens. The encapsulation body 4 may have a plurality of such local curved surfaces. In particular, each of the unit cells 10T has such a sub-region 4T with a curved top side 41.

Alternatively or additionally, it is possible for the top side 41 to have microstructures, for example in the form of dome-like elevations, lens structures, pyramid shapes, or in the form of depressions which have lens shapes and/or pyramid shapes.

FIG. 2D shows a sub-region 3T of the reflector 3. In particular, this sub-region 3T is assigned to a unit cell 10T of the backlighting unit 10. The sub-region 3T is located in particular only on the outer region of the unit cell 10T. The sub-region 3T has an opening 30 in the form of a through-hole. The opening 30 is filled in particular by a sub-region 4T of the encapsulation body 4. In top view, the sub-region 3T of the reflector 3 can be completely covered by the encapsulation body 4.

The sub-region 3T or the reflector 3 has a highly reflective or Lambertian-scattering surface. In particular, a reflectance R of the surface of the reflector 3 is greater than 90%, for example greater than 95%. The sub-region 3T or the reflector 3 has side walls 3W that are oblique. For example, side walls 3W with a vertical plummet form an angle of inclination 3N from 30° to 60°, from 30° to 55° or from 30° to 45°. In FIG. 2D, the angle of inclination 3N is approximately 47°.

FIGS. 3A and 3B schematic representations of the results of a simulation with regard to the luminance distribution (FIG. 3A) and with regard to the chromaticity distribution (FIG. 3B) of a unit cell 10T. In the presence of the depressions 40, a particularly high degree of homogeneity can be achieved with regard to the luminance distribution and the chromaticity distribution.

FIG. 4A shows a reflector 3, such as a secondary reflector 3, with 25 sub-regions 3T, wherein the sub-regions 3T are each assigned to one of the unit cells 10T of the backlighting unit 10. The reflector 3 has a structure with oblique side walls at the edge region for delimiting the unit cells 10T and for preventing overcoupling in neighboring cells. The reflector 3 can be partially or completely embedded in the encapsulation body 4.

A corresponding encapsulation body 4 with 25 sub-regions 4T, each with a centrally arranged depression 40, is shown schematically in FIG. 4B. The depression 40 or the plurality of depressions 40 can be partially or completely filled with a partially transparent material, with a diffuse material, with a colored material, with a wavelength-converting material or with combinations thereof. However, it is also possible that the depression 40 or the plurality of depressions 40 are not filled with a solid material but with a gaseous material, such as air.

The encapsulation body 4 protrudes beyond the reflector 3 along the vertical direction, so that the reflector 3 is completely covered by the encapsulation body 4 when viewed from above. The encapsulation body 4 is continuous and made in one piece. The unit cells 10T can each have a lateral width or a lateral length of between 5 mm and 15 mm inclusive, for instance between 8 mm and 12 mm. However, the unit cells 10T are not limited to these geometric sizes.

It is possible that the material of the encapsulation body 4 is filled with diffusor particles of low concentration, such as less than 1 or less than 2 percent by weight. Alternatively or additionally, the material of the encapsulation body 4 can be filled with phosphor particles of low concentration, for example less than 5 percent by weight. In this case, the backlighting unit 10 may be provided with a separate phosphor layer 54 or without such a separate phosphor layer 54.

FIGS. 5A and 5B show schematic representations of a structured carrier 90 and an arrangement 100 with a backlighting unit 10 on a structured carrier 10.

As shown schematically in FIG. 2A, a non-negligible amount of radiation is emitted directly in the direction of the carrier 90. Electromagnetic radiation impinging on the carrier 90 directly next to the semiconductor chip 2 could be reflected back directly in a forward direction, namely in the z-direction. This would possibly lead to a hotspot.

This problem can be at least partially solved if a top side 91 of the carrier 90 is structured. In particular, the top side 91 of the carrier 90 has depressions and/or elevations in areas around the semiconductor chip 2. The structured top side 91 is particularly for achieving back reflection of the electromagnetic radiation generated by the semiconductor chip 2 and impinging on the carrier 90 to larger angles, in order to minimize the risk that an area of the carrier 90 around the semiconductor chip 2 will light up brightly and thus possibly lead to a hotspot.

The depressions or the elevations on the top side 91 of the carrier 90 may have a vertical depth or a vertical height from 0.1 mm to 0.5 mm, or from 0.15 mm to 0.45 mm, for example around 0.3 mm. The depressions or the elevations may have inner walls or side surfaces that form an angle of inclination with a vertical plummet of from 30° to 70°, such as from 30° to 60°, for example around 55°.

The top side 91 of the carrier 90 may have chamfers across large areas, such as those shown in FIG. 5A. Also, the top side 91 may have a plurality of smaller depressions or elevations whose geometric sizes remain the same or vary across the top side 91.

As shown schematically in FIG. 5B, a large part of the radiation impinging on the carrier 90 can be scattered or reflected back in the forward direction.

It is further possible that several semiconductor chips 2 are mounted in a unit cell 10T. For example, a unit cell 10T has three, four, six or more than 6 semiconductor chips 2. The semiconductor chips 2 can be arranged mirror-symmetrically to the xz and yz planes, point-symmetrically to the center of the unit cell 10T or randomly distributed. Such a unit cell 10T is shown schematically, for example, in FIGS. 6A, 6B, 6C, 6D and 6E. If the unit cell 10T is viewed from above, the semiconductor chips 2 are, for example, completely or partially mounted below the depression 4.

This application claims the priority of the German patent application DE 10 2021 119 175.0, the disclosure content of which is hereby included by reference.

The invention is not restricted to the exemplary embodiments by the description of the invention made with reference to the exemplary embodiments. The invention rather comprises any novel feature and any combination of features, including in particular any combination of features in the claims, even if this feature or this combination is not itself explicitly indicated in the patent claims or exemplary embodiments.

### LIST OF REFERENCE SYMBOLS

10 Backlighting unit
10V Top side of the backlighting unit
10R Bottom side of the backlighting unit
10H Vertical total height of the backlighting unit
10T Unit cell of the backlighting unit
2 Semiconductor chip
21 First semiconductor layer
22 Second semiconductor layer
23 Active zone
2K Contact structure of the semiconductor chip
2V Top side of the semiconductor chip
2R Bottom side of the semiconductor chip
2S Side surface of the semiconductor chip
3 Reflector
30 Opening of the reflector
3T Sub-region of the reflector
3R Edge region of sub-region 3T of the reflector
3W Side wall of the reflector
4 Encapsulation body
41 Top side of the encapsulation body
41N Angle of inclination of the top side of the encapsulation body
42 Bottom side of the encapsulation body
40T Sub-region of the encapsulation body
40 Depression of the encapsulation body
40B Bottom surface of the depression
40K Edge of the depression
40W Side wall of the depression
40N Angle of inclination of the side wall
4H Height of the encapsulation body
4A Distance between the bottom side of the encapsulation body and the bottom surface of the depression
45 Intermediate gap
5 Cover layer stack
51 Top side of the cover layer stack
52 Bottom side of the cover layer stack
54 Phosphor layer
55 Diffuser layer
56 Brightness enhancement film, BEF
59 Functional layer
90 Carrier
91 Top side of the carrier
90K Contact structure of the carrier
100 Arrangement with backlighting unit and carrier

1. A backlighting unit comprising at least one semiconductor chip, a reflector and an encapsulation body, wherein
the semiconductor chip is configured to generate electromagnetic radiation,
the encapsulation body has at least one depression, the semiconductor chip is arranged outside the depression and overlaps with the depression in top view of the encapsulation body,
the semiconductor chip is a side-emitting semiconductor chip,
the reflector has at least one frame-like sub-region, the opening of which is filled by material of the encapsulation body and encloses the semiconductor chip and the depression of the encapsulation body in lateral directions, and
the encapsulation body projects beyond the sub-region in the vertical direction, wherein in top view, the encapsulation body at least partially or completely covers edge regions of the sub-region.

2. The backlighting unit according to claim 1, wherein the semiconductor chip is enclosed by the encapsulation body at least in lateral directions.

3. The backlighting unit according to claim 1, wherein the depression is formed in the shape of a pyramid or truncated pyramid and has a cross-section that becomes larger with increasing distance from the semiconductor chip, wherein the depression has a bottom surface that is flat.

4. The backlighting unit according to claim 1, wherein the depression comprises side which are convexly or concavely curved.

5. The backlighting unit according to claim 1, wherein the depression has edges which are rounded.

6. The backlighting unit according to claim 1, wherein the depression is filled with a gaseous medium.

7. The backlighting unit according to claim 1, wherein the depression is filled with a partially transparent material, a diffuse material, a colored material and/or with a wavelength-converting material.

8. The backlighting unit according to claim 1, comprising a cover layer stack which overlies the encapsulation body and completely covers the depression.

9. The backlighting unit according to claim 8, wherein a vertical expansion of the backlighting unit is delimited by a top side of the cover layer stack and a bottom side of the encapsulation body, and wherein a total vertical height of the backlighting unit given by a vertical distance between the top side of the cover layer stack and the bottom side of the encapsulation body is at most 3 mm.

10. The backlighting unit according to claim 8, wherein the encapsulation body has a top side which is curved, as a result of which there is in places an intermediate gap between the encapsulation body and the cover layer stack.

11. The backlighting unit according to claim 8, wherein the cover layer stack comprises at least one or more layers from a group of functional layers, wherein the group of functional layers includes a phosphor layer, a diffuser layer and/or so-called brightness enhancement films.

12. The backlighting unit according to claim 1, comprising a plurality of semiconductor chips, wherein
the backlighting unit has a plurality of unit cells each comprising one of the semiconductor chips,
the encapsulation body has a plurality of sub-regions each comprising a depression,
the sub-regions of the encapsulation body each laterally enclose one of the semiconductor chips, the one semiconductor chip being arranged outside the depression associated therewith and overlapping with the depression associated therewith in top view of the encapsulation body, and
the sub-regions of the encapsulation body are each assigned to one of the unit cells.

13. The backlighting unit according to claim 12, wherein
the reflector is a common reflector comprising a plurality of contiguous sub-regions each associated with one of the unit cells, and
the encapsulation body comprising its sub-regions is contiguous.

14. An arrangement comprising the backlighting unit according to claim 1 and a carrier, wherein
the backlighting unit is arranged on the carrier, and
the semiconductor chip is electrically externally connectable via contact structures on the carrier.

15. An arrangement comprising the backlighting unit according to claim 1 and a carrier, wherein
the backlighting unit is arranged on the carrier,
the carrier has a structured top side facing the backlighting unit, and
the structured top side is configured to scatter the electromagnetic radiation, which is generated by the semiconductor chip and impinges on the carrier, and thus to prevent possible hotspots.

16. The backlighting unit according to claim 1, wherein the encapsulation body is continuous and formed in one piece, and wherein the side-emitting semiconductor chip is partially or completely embedded in the encapsulation body.
